(19) United States
(12) Patent Application Publication
(10) Pub. No.: US 2023/0225225 A1
(43) Pub. Date: Jul. 13, 2023

(54) SYSTEM AND METHOD FOR SUPERCONDUCTING SILICON INTERCONNECT SUBSTRATE WITH SUPERCONDUCTING QUANTUM PROCESSOR

(71) Applicant: The Regents of the University of California, Oakland, CA (US)

(72) Inventors: Yu-Tao YANG, Los Angeles, CA (US); Subramanian S. IYER, Los Angeles, CA (US)

(73) Assignee: The Regents of the University of California, Oakland, CA (US)

(21) Appl. No.: 18/000,377

(22) PCT Filed: May 27, 2021
(86) PCT No.: PCT/US2021/034604

§ 371 Date: Nov. 30, 2022

Related U.S. Application Data
(60) Provisional application No. 63/032,980, filed on Jun. 1, 2020.

(51) Int. Cl. H10N 69/00; G06N 10/40

(52) U.S. Cl. CPC H10N 69/00; G06N 10/40

(57) ABSTRACT

Example implementations include a method of manufacturing a quantum computing device, by depositing a superconducting electrode layer on at least a portion of a superconducting wafer, forming a plurality of electrode pads on the superconducting electrode layer, depositing an electrode bonding interlayer on the electrode pads, singulating the superconducting wafer into a first superconducting die including a first electrode pad among the plurality and a second superconducting die including a second electrode pad among the plurality, and integrating the first superconducting die with the second superconducting die at a bonding interface between the first electrode pad and the second electrode pad.

### CROSS-REFERENCE TO RELATED PATENT APPLICATIONS

This application claims priority to U.S. Provisional Patent Application Ser. No. 63/032,980, entitled “APPARATUS AND METHOD OF MAKING SUPERCONDUCTING SILICON INTERCONNECT FABRIC,” filed Jun. 1, 2020, the contents of all such applications being hereby incorporated by reference in its entirety and for all purposes as if completely and fully set forth herein.

### FEDERALLY SPONSORED RESEARCH OR DEVELOPMENT

This invention was made with government support under Grant Number N00014-18-1-2638, awarded by the U.S. Navy, Office of Naval Research. The government has certain rights in the invention.

### TECHNICAL FIELD

The present implementations relate generally to quantum computing, and more particularly to a superconducting silicon interconnect substrate with a superconducting quantum processor.

### BACKGROUND

Quantum computing is becoming increasingly desirable for increasingly complex computing applications. Further, superconducting quantum computing is increasingly desirable to realize reliable quantum computing systems. Superconducting quantum computing devices operating at superconducting temperatures approaching absolute zero require specific communication channels for communicating with control and input logic operating at semiconductor, or room, temperature. However, conventional systems require bulky and low-speed communication channels that impede and prevent scaling of superconducting quantum computing systems to processing size and speed sufficient for practical applications.

### SUMMARY

Present implementations are directed to a superconducting silicon interconnect substrate with a superconducting quantum processor, to provide both superconducting processing and superconducting communication channels to control and input logic. By providing superconducting communication channels with superconducting electronic devices on a superconducting silicon interconnect substrate, processing delay can be substantially reduced by multiple orders of magnitude from the millisecond (ms) range to the picosecond (ps) range. Further, by providing superconducting a quantum processor and superconducting electronic devices on a superconducting silicon interconnect substrate, computation density can be increased by multiple orders of magnitude from hundreds of quantum bits (qubits) to up to 100 million qubits. Thus, a technological solution for a superconducting silicon interconnect substrate with a superconducting quantum processor is provided.

Example implementations include a quantum computing device with a quantum processor operable at a cryogenic temperature, a superconducting input controller operable at the cryogenic temperature and operatively coupled to the quantum processor by a first digital input channel, and a superconducting output controller operable at the cryogenic temperature and operatively coupled to the quantum processor by a second digital input channel.

Example implementations include a quantum computing device where the first digital input channel and the second digital input channel each respectively include a single flux quantum digital channel.

Example implementations include a quantum computing device with a superconducting interconnect substrate operable at the cryogenic temperature, including an interconnect electrode pad disposed thereon, and operatively coupled at the interconnect electrode pad to a corresponding interconnect electrode pad of the quantum processor.

Example implementations include a quantum computing device where the first interconnect electrode pad is integrated with the interconnect electrode pad.

Example implementations include a quantum computing device where the first interconnect electrode pad is integrated with the interconnect electrode pad at a bonding interface therebetween.

Example implementations include a quantum computing device where the bonding interface can withstand a shear force of up to 150 N.

Example implementations include a quantum computing device where the superconducting input controller includes a microwave input processor operable to receive one or more analog microwave signals.

Example implementations include a quantum computing device where the superconducting input controller includes a microwave input processor operable to generate one or more single flux quantum digital signals.

Example implementations include a quantum computing device where the superconducting output controller includes a Josephson photomultiplier operable to receive one or more single flux quantum digital signals.

Example implementations include a quantum computing device where the superconducting output controller includes a Josephson photomultiplier operable to generate one or more corresponding binary signals.

Example implementations include a quantum processor device with a superconducting interconnect substrate operable at a cryogenic temperature, and a plurality of qubit dies operable at the cryogenic temperature and operatively coupled to the superconducting interconnect substrate.

Example implementations include a quantum computing device where the plurality of qubit dies is integrated with the superconducting interconnect substrate at a bonding interface between a corresponding qubit die electrode pad and a corresponding interconnect substrate electrode pad.

Example implementations include a quantum processor device where the bonding interface can withstand a shear force of up to 150 N.

Example implementations include a quantum computing device where each of the plurality of qubit dies respectively includes the corresponding qubit die electrode pad.

Example implementations include a quantum computing device where the superconducting interconnect substrate includes a corresponding interconnect substrate electrode pad.

Example implementations include a method of manufacturing a quantum computing device, by depositing a superconducting electrode layer on at least a portion of a superconducting wafer, forming a plurality of electrode pads on the superconducting electrode layer, depositing an electrode bonding interlayer on the electrode pads, singulating the superconducting wafer into a first superconducting die including a first electrode pad among the plurality and a second superconducting die including a second electrode pad among the plurality, and integrating the first superconducting die with the second superconducting die at a bonding interface between the first electrode pad and the second electrode pad.

Example implementations include a method of manufacturing a quantum computing device by further depositing an anticorrosion layer on the superconducting electrode layer.

Example implementations include a method of manufacturing a quantum computing device where the forming the plurality of electrode pads further includes forming the plurality of electrode pads on the superconducting electrode layer and the anticorrosion layer.

Example implementations include a method of manufacturing a quantum computing device where the integrating the first superconducting die with the second superconducting die further includes applying pressure of up to 300N to the first superconducting die and the second superconducting die.

Example implementations include a method of manufacturing a quantum computing device where the integrating the first superconducting die with the second superconducting die further includes applying pressure at up to 140° C. to the first superconducting die and the second superconducting die.

Example implementations include a method of manufacturing a quantum computing device where the applying the pressure further includes applying pressure in a direction substantially orthogonal to a planar surface corresponding to the bonding interface.

Example implementations include a method of manufacturing a quantum computing device by further contacting the first electrode pad to the second electrode pad by flipping the first superconducting die or the second superconducting die.

Example implementations include a method of manufacturing a quantum computing device where the superconducting electrode layer includes niobium.

Example implementations include a method of manufacturing a quantum computing device where the anticorrosion layer includes iridium.

Example implementations include a method of manufacturing a quantum computing device where the electrode bonding interlayer includes gold.

Example implementations include a method of manufacturing a quantum computing device where the electrode bonding interlayer further includes titanium.

Example implementations include a method of manufacturing a quantum computing device where the depositing the superconducting electrode layer includes depositing the superconducting electrode layer by sputtering.

Example implementations include a method of manufacturing a quantum computing device where the depositing the anticorrosion layer includes depositing the anticorrosion layer by sputtering.

Example implementations include a method of manufacturing a quantum computing device where the depositing the electrode bonding interlayer includes depositing the electrode bonding interlayer by evaporation.

### BRIEF DESCRIPTION OF THE DRAWINGS

These and other aspects and features of the present implementations will become apparent to those ordinarily skilled in the art upon review of the following description of specific implementations in conjunction with the accompanying figures, wherein:

FIG. 1 illustrates an example system in accordance with present implementations.

FIG. 2 illustrates an example device in accordance with present implementations.

FIG. 3 illustrates an example quantum processor device further to the example device of FIG. 2.

FIG. 4 illustrates an example cross sectional-view of a portion of a superconducting silicon interconnect substrate with a superconducting quantum processor device, further to the example device of FIG. 3.

FIG. 5 illustrates an example method of manufacturing a superconducting silicon interconnect substrate with a superconducting quantum processor, in accordance with present implementations.

FIG. 6 illustrates an example method of manufacturing a superconducting silicon interconnect substrate with a superconducting quantum processor further to the example method of FIG. 5.

FIG. 7 illustrates an example method of manufacturing a superconducting silicon interconnect substrate with a superconducting quantum processor further to the example method of FIG. 6.

FIG. 8 illustrates a further example method of manufacturing a superconducting silicon interconnect substrate with a superconducting quantum processor, in accordance with present implementations.

### DETAILED DESCRIPTION

The present implementations will now be described in detail with reference to the drawings, which are provided as illustrative examples of the implementations so as to enable those skilled in the art to practice the implementations and alternatives apparent to those skilled in the art. Notably, the figures and examples below are not meant to limit the scope of the present implementations to a single implementation, but other implementations are possible by way of interchange of some or all of the described or illustrated elements. Moreover, where certain elements of the present implementations can be partially or fully implemented using known components, only those portions of such known components that are necessary for an understanding of the present implementations will be described, and detailed descriptions of other portions of such known components will be omitted so as not to obscure the present implementations. Implementations described as being implemented in software should not be limited thereto, but can include implementations implemented in hardware, or combinations of software and hardware, and vice-versa, as will be apparent to those skilled in the art, unless otherwise specified herein. In the present specification, an implementation showing a singular component should not be considered limiting; rather, the present disclosure is intended to encompass other implementations including a plurality of the same component, and vice-versa, unless explicitly stated otherwise herein. Moreover, applicants do not intend for any term in the specification or claims to be ascribed an uncommon or special meaning unless explicitly set forth as such. Further, the present implementations encompass present and future known equivalents to the known components referred to herein by way of illustration.

Present implementations achieve low-error and low-latency quantum computing are significantly increased quantum bit (qubit) density and capacity, by a superconducting silicon interconnect substrate with a superconducting quantum processor. The superconducting silicon interconnect can include a silicon quantum processor and superconducting silicon electronic devices for processing signals to and from the quantum processor. By operating all of the superconducting silicon interconnect substrate, the superconducting quantum processor, and the superconducting silicon electronic devices at a cryogenic temperature, significant improvements in latency, error rate, clock speed, power dissipation, and qubit ceiling can be advantageously achieved by multiple orders of magnitude. Present implementations can provide communication from a quantum processor to various electronics within a superconducting environment and independently of a system processor operating at a room temperature, by a digital electronic communication channel having latency from the nanosecond (ns) to the picosecond (ps) range. With a digital communication channel through the superconducting silicon interconnect, significant amounts of device communication with the quantum processor can be maintained with the silicon system at the superconducting temperature to eliminate significant corresponding communication that otherwise would otherwise travel by analog microwave signaling at ns to millisecond (ms) latency between the superconducting system at cryogenic temperature to the system process operating at room temperature. Concurrently, present implementations can achieve a lower power dissipation of substantially

Integration of the superconducting silicon interconnect substrate with dies of the quantum processor by a flip-chip technique also substantially increases qubit capacity and mechanical stress resistance. Qubit capacity by integration of the superconducting silicon interconnect substrate with dies of the quantum processor in accordance with present implementations can increase capacity to the range of 100 million qubits, from otherwise being limited to hundreds of qubits in conventional systems. System errors rates from this configuration can also be reduced at least an order of magnitude from 10⁻² or 10⁻³ errors to 10⁻⁴ errors per representative sample of instructions, under present implementations, and can achieve a concurrent increase in clock speed to substantially 40 GHz from levels otherwise limited to 2 GHz. By flip-chip bonding in accordance with present implementations, dies of the quantum processor and the superconducting silicon electronic devices integrated with the superconducting silicon interconnect substrate can withstand significant shear forces as well. Specifically, bonding interfaces between the superconducting silicon interconnect substrate and the quantum processor or the superconducting silicon electronic devices can withstand shear forces of substantially 150 N. Thus, present implementations can advantageously achieve, by at least die integration on a superconducting silicon interconnect substrate, significant advantages in computational performance, quantum computational capacity, and

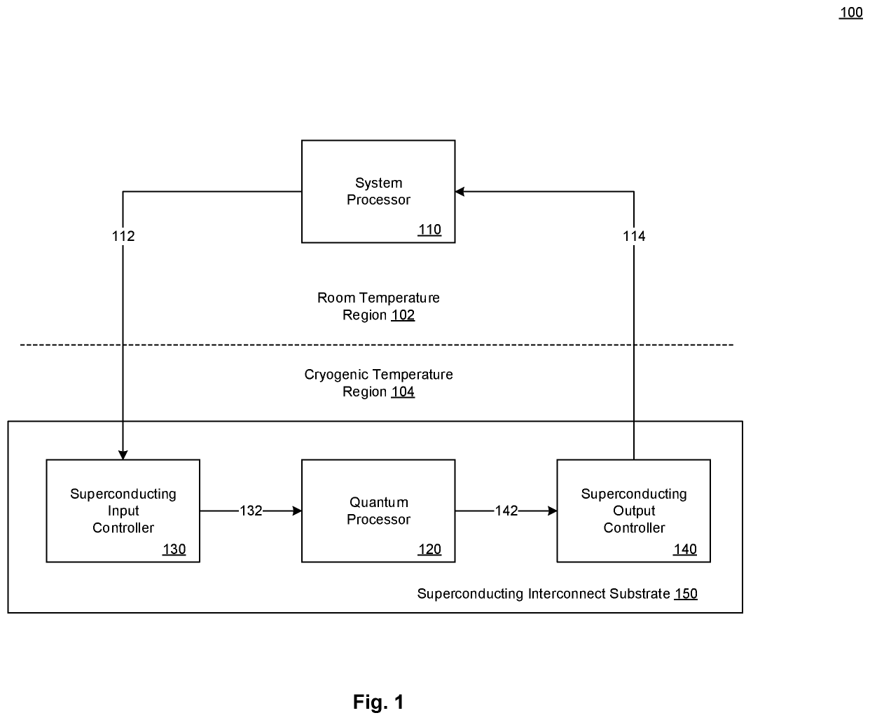

FIG. 1 illustrates an example system in accordance with present implementations. As illustrated by way of example in FIG. 1, an example system 100 includes a system processor 110 operating at a room temperature in a room temperature region 102, and a quantum processor 120, a superconducting input controller 130, a superconducting output controller 140, and a superconducting interconnect substrate 150 operating at a cryogenic temperature in a cryogenic temperature region 104.

The room temperature region 102 includes all system components operating substantially at a temperature supporting semiconducting behavior of electrical devices. As one example, room temperature can be substantially 68° F. As another example, room temperature can be any temperature above the freezing point of water. As another example, room temperature can be any temperature above a temperature activating superconducting properties of the quantum processor 120, the superconducting input controller 130, and the superconducting output controller 140. In some implementations, the room temperature region 102 is disposed outside of a cooler, freezer, refrigerator, or the like, housing one or more of the quantum processor 120, the superconducting input controller 130, and the superconducting output controller 140.

The cryogenic temperature region 104 includes all system components operating substantially at a temperature supporting superconducting behavior of electrical devices. As one example, cryogenic temperature can be substantially 68° F. As another example, cryogenic temperature can be any temperature below the freezing point of water. As another example, cryogenic temperature can be any temperature at or below a temperature activating superconducting properties of the quantum processor 120, the superconducting input controller 130, and the superconducting output controller 140. In some implementations, the cryogenic temperature region 104 is disposed within of a cooler, freezer, refrigerator, or the like, housing one or more of the quantum processor 120, the superconducting input controller 130, and the superconducting output controller 140.

The system processor 110 is operable to execute one or more binary instructions associated with one or more of the quantum processor 120, the superconducting input controller 130, and the superconducting output controller 140. In some implementations, the system processor 110 is an electronic processor, an integrated circuit, or the like including one or more of digital logic, analog logic, digital sensors, analog sensors, communication buses, volatile memory, nonvolatile memory, and the like. In some implementations, the system processor 110 includes but is not limited to, at least one microcontroller unit (MCU), microprocessor unit (VIPU), central processing unit (CPU), graphics processing unit (GPU), physics processing unit (PPU), embedded controller (EC), or the like. In some implementations, the system processor 110 includes a memory operable to store or storing one or more instructions for operating components of the system processor 110 and operating components operably coupled to the system processor 110. In some implementations, the one or more instructions include at least one of firmware, software, hardware, operating systems, embedded operating systems, and the like. The system processor 110 can be operatively coupled to the superconducting input controller 130 by a system instruction channel 112, and can be operatively coupled to the superconducting output controller 140 by the system readout channel 114. It is to be understood that the system processor 110 can generate, receive, or the like, one or more instruction for quantum computation based on external user input, instructions stored locally or remotely at a system memory, and the like.

The system instruction channel 112 is operable to transmit one or more instructions from the system processor 110 to the superconducting input controller 130. The system instruction channel 112 can be a wireless communication channel supporting a communication from a room temperature region 102 to a cryogenic temperature region 104. As one example, the system instruction channel 112 can include a microwave transmitter operatively and wirelessly coupled to a corresponding microwave receiver at, with, in, or the like, the superconducting input controller 130. The microwave transmitter can transmit an instruction across any boundary between the room temperature region 102 and the cryogenic temperature region 104. As one example, the microwave transmitter can transmit an instruction through and into a cryogenic refrigerator enclosing the quantum processor 120, the superconducting input controller 130, and the superconducting output controller 140. In some implementations, the system processor 110 can include a microwave transmitter, be operatively coupled to a microwave transmitter, or the like.

The system readout channel 114 is operable to receive one or more instructions at the system processor 110 from the superconducting output controller 140. The system readout channel 114 can be a wireless communication channel supporting a communication to a room temperature region 102 from a cryogenic temperature region 104. As one example, the system readout channel 114 can include a microwave receiver operatively and wirelessly coupled to a corresponding microwave transmitter at, with, in, or the like, the superconducting input controller 130. The microwave receiver can receive an instruction across any boundary between the room temperature region 102 and the cryogenic temperature region 104. As one example, the microwave receiver can receive an instruction through and from a cryogenic refrigerator enclosing the quantum processor 120, the superconducting input controller 130, and the superconducting output controller 140. In some implementations, the system processor 110 can include a microwave transmitter, be operatively coupled to a microwave transmitter, or the like.

The quantum processor 120 is operable to execute one or more quantum instructions associated with one or more of the system processor 110, the superconducting input controller 130, and the superconducting output controller 140. In some implementations, the quantum processor 120 is an electronic processor, an integrated circuit, or the like including one or more of digital logic, analog logic, digital sensors, analog sensors, communication buses, volatile memory, nonvolatile memory, and the like. In some implementations, the quantum processor 120 includes but is not limited to, at least one qubit instruction register, qubit arithmetic unit, qubit firmware, and the like. The quantum processor can execute one or more quantum instructions based on qubits that can have a first binary state (e.g., “1”), a second binary state (e.g., “0”), and a quantum state (e.g., “1 and 0”). In some implementations, the quantum processor 120 includes a memory operable to store or storing one or more instructions for operating components of the quantum processor 120 and operating components operably coupled to the quantum processor 120. In some implementations, the one or more instructions include at least one of firmware, software, hardware, operating systems, embedded operating systems, and the like. The quantum processor 120 can be operatively coupled to the superconducting input controller 130 by superconducting processor input channel 132, and can be operatively coupled to the superconducting output controller 140 by superconducting processor output channel 142.

The superconducting input controller 130 is operable to receive one or more instructions from the system processor 100 and to provide one or more instructions to the quantum processor 300 from within the cryogenic temperature region. The superconducting input controller 130 can also perform a number of operations for control and management of execution of quantum instructions by the quantum processor 300. The superconducting input controller 130 can provide digital instructions to the quantum processor based on instructions received from the system processor 110, and can also provide digital instructions to the quantum processor 300 for control and management of execution of quantum instructions by the quantum processor 300, including clock management. The superconducting input controller 130 can be operatively coupled to the quantum processor 120 by a superconducting processor input channel 132.

The superconducting processor input channel 132 includes a digital communication channel operatively coupling the superconducting input controller 130 to the quantum processor 300. The superconducting processor input channel 132 can include a portion of a superconducting silicon interconnect substrate having one or more traces, layers, regions, and the like in contact with one or more electrode pads, interconnects, and the like, of the quantum processor 300 and one or more superconducting silicon electronic devices.

The superconducting output controller 140 is operable to transmit one or more instructions to the system processor 100 and to receive one or more instructions from the quantum processor 300 from within the cryogenic temperature region. The superconducting output controller 140 can also perform a number of operations for control and management of execution of quantum instructions by the quantum processor 300, including control and management operations distinct from those provided by the superconducting input controller 130. The superconducting output controller 140 can receive digital instructions from the quantum processor based on instructions received from the system processor 110, and can also provide digital instructions to the quantum processor 300 for control and management of execution of quantum instructions by the quantum processor 300, including signal multiplexing and quantum readout to binary digital states. The superconducting output controller 140 can be operatively coupled to the quantum processor 120 by a superconducting processor output channel 142.

The superconducting processor output channel 142 includes a digital communication channel operatively coupling the superconducting out controller 140 to the quantum processor 300. The superconducting processor output channel 142 can include a portion of a superconducting silicon interconnect substrate having one or more traces, layers, regions, and the like in contact with one or more electrode pads, interconnects, and the like, of the quantum processor 300 and one or more superconducting silicon electronic devices.

The superconducting interconnect substrate 150 includes at least one portion of a semiconductor wafer, die or the like including at least one interconnect pattern to operatively couple one or more of superconducting input controller 130, the quantum processor 120, and the superconducting output controller 140 to each other. The superconducting interconnect substrate 150 can include one or more circuits, traces, and the like fabricated therein, thereon, on the like, and can include one or more of the superconducting processor input channel 132 and the superconducting processor output channel 142 therein.

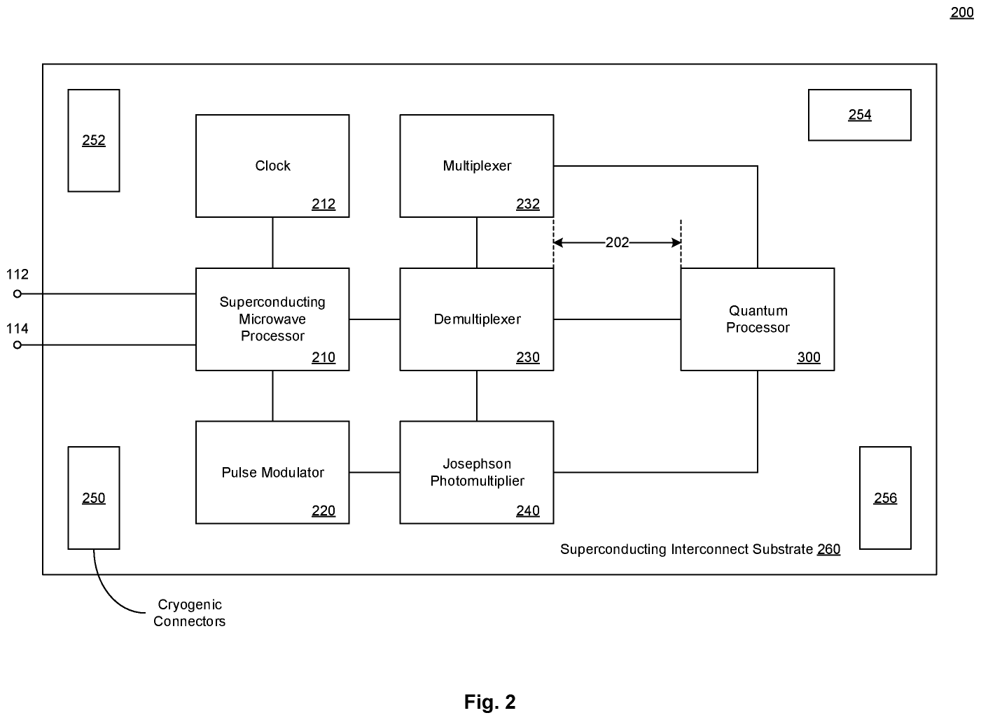

FIG. 2 illustrates an example device in accordance with present implementations. As illustrated by way of example in FIG. 2, an example device 200 includes a superconducting microwave processor 210, a clock 212, a pulse modulator 220, a demultiplexer 230, a multiplexer 232, a Josephson photomultiplier 240, cryogenic connectors 250, 252, 254 and 256, and a quantum processor 300, disposed on a superconducting interconnect substrate 260. It is to be understood that the superconducting microwave processor 210, the clock 212, the pulse modulator 220, the demultiplexer 230, the multiplexer 232, and the Josephson photomultiplier 240, can be singulated from dies having various sizes. As one example, die sizes for these devices can be 3 mm by 3 mm, 4 mm by 4 mm, and 5 mm by 5 mm.

It is to be understood that additional superconducting control electronics can be disposed on the superconducting interconnect substrate 260. These additional superconducting control electronics can be one or more devices operatively coupled to one or more of the superconducting microwave processor 210, the clock 212, the pulse modulator 220, the demultiplexer 230, the multiplexer 232, and the Josephson photomultiplier 240. As one example, a first additional superconducting control electronic device can be disposed between and operatively coupled at least to the clock 212 and the multiplexer 232. As another example, a second additional superconducting control electronic device can be disposed between and operatively coupled at least to the superconducting microwave processor 210 and the demultiplexer 230. As another example, a third additional superconducting control electronic device can be disposed between and operatively coupled at least to the pulse modulator 220 and the Josephson photomultiplier 240.

The superconducting microwave processor 210 includes at least one superconducting analog signal processor, at least one superconducting digital signal processor, and at least one superconducting analog transceiver. The superconducting microwave processor 210 can both receive microwave signals from the system processor 110 and transmit microwave signals to the system processor 110 based on computational instructions for input to the quantum processor 300 and computational results generated by the quantum processor 300. It is to be understood that all of the components of the superconducting microwave processor 210 can operate at cryogenic temperature. It is to be further understood that all of the components of the superconducting microwave processor 210 can execute single flux quantum (SFQ) control and readout to the system processor 110. Present implementations including SFQ superconducting electronic devices can achieve power consumption with thousands of gates can at less than 10 μW, which is much less than the millikelvin cooling power. Thus, in some implementations, heat generation of superconducting circuits in accordance with present implementations can be significantly decreased.

The clock 212 includes at least one superconducting clock circuit operable to provide timing to one or more of the superconducting microwave processor 210, the pulse modulator 220, the demultiplexer 230, the multiplexer 232, the Josephson photomultiplier 240, and the quantum processor 300. The clock can provide a timing signal directly applicable to one or more of the superconducting microwave processor 210, the demultiplexer 230, the multiplexer 232, the Josephson photomultiplier 240, and the quantum processor 300, or indirectly applicable to one or more of the superconducting microwave processor 210, the demultiplexer 230, the multiplexer 232, the Josephson photomultiplier 240, and the quantum processor 300 by the pulse modulator 220. The clock 212 can substantially advantageously provide higher quantum computing speeds and achieve higher quantum computation capacity by co-locating the clock 212 with the quantum processor 300 in the cryogenic temperature region 104 and at the superconducting interconnect substrate 260.

The pulse modulator 220 includes at least one superconducting pulse width modulator circuit operable to provide at least one timing waveform to one or more of the superconducting microwave processor 210, the demultiplexer 230, the multiplexer 232, the Josephson photomultiplier 240, and the quantum processor 300. The pulse modulator 220 can generate at least one square waveform indicating having at least one pulse-width corresponding to a duty cycle for operating one or more of the superconducting microwave processor 210, the demultiplexer 230, the multiplexer 232, the Josephson photomultiplier 240, and the quantum processor 300. The pulse modulator 220 can substantially advantageously provide higher quantum computing speeds and achieve higher quantum computation capacity by being co-located with the quantum processor 300 in the cryogenic temperature region 104 and at the superconducting interconnect substrate 260.

The demultiplexer 230 and the multiplexer 232 include at least one superconducting circuit to respectively demultiplex and multiplex input and output of the quantum processor 300. The demultiplexer 230 and the multiplexer 232 can substantially advantageously provide higher quantum computing speeds and achieve higher quantum computation capacity by being co-located with the quantum processor 300 in the cryogenic temperature region 104 and at the superconducting interconnect substrate 260.

The Josephson photomultiplier 240 includes one or more circuits to generate a binary result based on one or more quantum results. The Josephson photomultiplier 240 can advantageously generate a binary result of projective quantum measurements at the millikelvin stage without wiring back to the system processor 110 for heterodyning and thresholding measurements. The Josephson photomultiplier 240 can substantially advantageously provide higher quantum computing speeds and achieve higher quantum computation capacity by being co-located with the quantum processor 300 in the cryogenic temperature region 104 and at the superconducting interconnect substrate 260.

The cryogenic connectors 250, 252, 254 and 256 include one or more temperature devices to apply and maintain a cryogenic temperature at the superconducting microwave processor 210, the clock 212, the pulse modulator 220, the demultiplexer 230, the multiplexer 232, the Josephson photomultiplier 240, the quantum processor 300, and the superconducting interconnect substrate 260. As one example, the cryogenic connectors 250, 252, 254 and 256 can be one or more of mercury microconnectors, spring probes, and fuzz buttons. The mercury microconnectors can use the liquid/solid phase change of mercury at different temperatures to transition between room and cryogenic temperatures. This phase change provides a buffer to avoid connectors cracking while cooling down. Micro pins inside mercury micro-connectors can be fabricated by electrodischarge machining (EDM) and can be made a few hundreds of micrometers in size. Spring probes can have a spring pitch of 400 μm or less. Fuzz buttons can be gold-plated beryllium copper and can have a smallest dimension of 400 μm. Thus, in some implementations, the cryogenic connectors 250, 252, 254 and 256 can provide temperature buffer and withstand thermal contraction and expansion during cooling and warming of superconducting devices.

The quantum processor 300 includes one or more superconducting dies including one or more qubit-based processing cores. It is to be understood that the quantum processor 300 can correspond in one or more of operation and structure to the quantum processor 130. The quantum processor 300 can be disposed away from the superconducting electronic devices by an isolation gap 202. the quantum processor can include one or more shielding bonding traces along one or more side thereof.

The isolation gap 202 includes a predetermined portion of the superconducting interconnect substrate 260 isolating the quantum processor 300 from the other superconducting devices disposed on the superconducting interconnect substrate 260. A critical issue related to integrating SFQ circuits on the same board with qubit dies is noise, which can affect qubits in the form of interference from phonons and unpaired quasiparticles. The isolation gap 202 can advantageously isolate the quantum processor 300 from the superconducting device on the superconducting interconnect substrate 260, allowing phonons and quasiparticles originating therefrom to decay and combine before reaching the quantum processor 300. However, an inter-die gap between superconducting devices on the superconducting interconnect substrate 260 can be less than or equal to 100 μm.

The superconducting interconnect substrate 260 includes at least one portion of a semiconductor wafer, die or the like including at least one interconnect pattern to operatively couple one or more of the superconducting microwave processor 210, the clock 212, the pulse modulator 220, the demultiplexer 230, the multiplexer 232, the Josephson photomultiplier 240, and the quantum processor 300 to each other. The superconducting interconnect substrate 260 can substantially advantageously provide higher quantum computing speeds and achieve higher quantum computation capacity by being co-located with the quantum processor 300 in the cryogenic temperature region 104 and allowing all other superconducting devices on the superconducting interconnect substrate 260 to be co-located with the quantum processor 300.

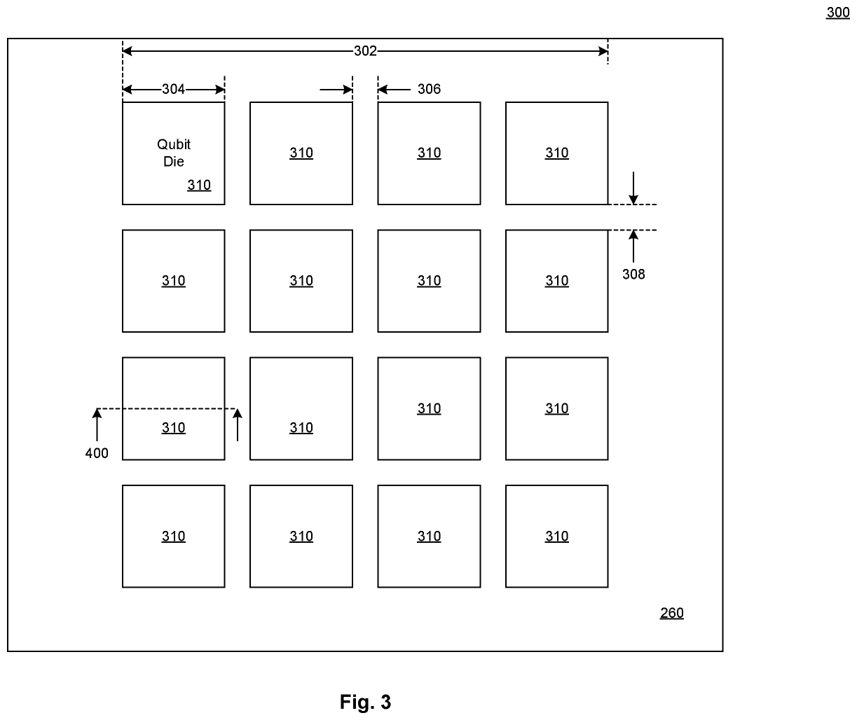

FIG. 3 illustrates an example quantum processor device further to the example device of FIG. 2. As illustrated by way of example in FIG. 3, an example quantum processor device 300 includes a plurality of qubit dies 310 disposed on the superconducting interconnect substrate 260.

The qubit dies 310 include including one or more qubit-based processing cores. The quantum processor 300 can be advantageously divided into qubit die 310 to further reduce noise from phonons and quasiparticles. As one example, the qubit dies 310 are combined into the quantum processor 310 by large die stitching. The die stitching method breaks the common Si plane, which is the diffusion path for the particles and the vibration waves. The qubit dies 310 can have a die side length 304, and be disposed on the superconducting interconnect substrate 260 across a processor side length 302 at a die gap 306.

The processor side length 302 extends the length of the quantum processor 300, and includes all of the qubit dies in a length direction. It is to be understood that the quantum processor 300 can be a square or substantially square in shape in a plan view thereof, and the processor side length 302 can correspond to a length for all sides of the quantum processor 300. As one example, the processor side length 302 can be substantially 8 mm.

The die side length 304 extends the length of the qubit die 310, and corresponds to a length of all of the qubit dies 310 in a length direction. It is to be understood that the qubit dies 310 can be a square or substantially square in shape in a plan view thereof, and the die side length 304 can correspond to a length for all sides of the qubit die 304. As one example, the die side length 304 can be substantially 2 mm.

The die gap 306 includes a predetermined portion of the superconducting interconnect substrate 260 isolating each qubit die 310 on the superconducting interconnect substrate 260 from each other. Similarly to issues related to the isolation gap 202, interference from phonons and unpaired quasiparticles can affect qubit dies 310 in the form of interference from phonons and unpaired quasiparticles. The die gap 306 can advantageously isolate the qubit dies 310 from the on the superconducting interconnect substrate 260 from each other, allowing phonons and quasiparticles originating therefrom to decay and combine before reaching the neighboring qubit die or dies 310.

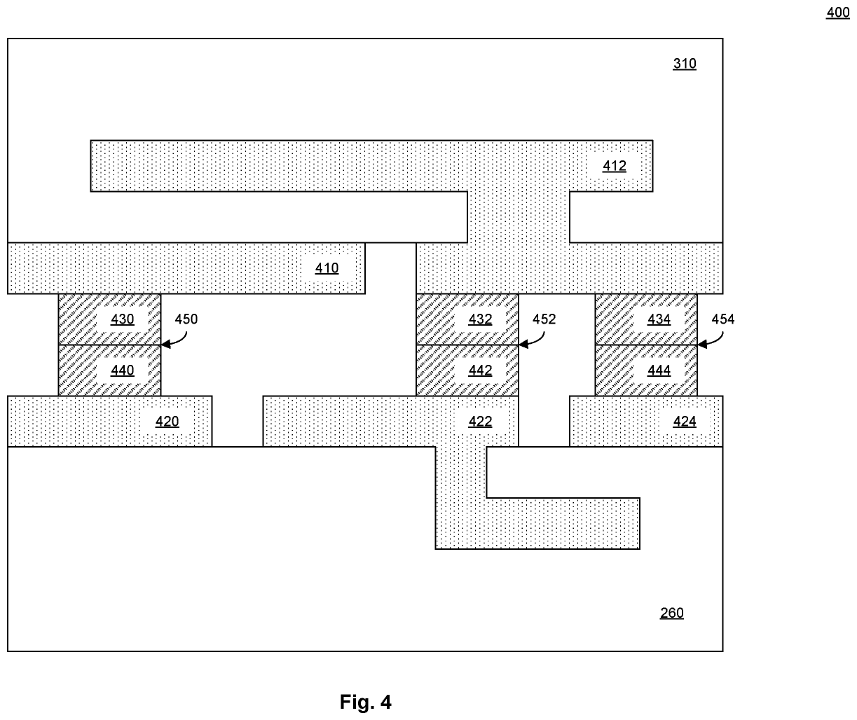

FIG. 4 illustrates an example cross sectional-view of a portion of a superconducting silicon interconnect substrate with a superconducting quantum processor device, further to the example device of FIG. 3. As illustrated by way of example in FIG. 4, an example device 400 includes the die 310 and the superconducting interconnect substrate 260.

The die 310 corresponds to one of the qubit dies 310, and can correspond to any of the superconducting microwave processor 210, the clock 212, the pulse modulator 220, the demultiplexer 230, the multiplexer 232, the Josephson photomultiplier 240, and the quantum processor 300. It is to be understood that the devices noted above can be operatively coupled to, integrated with, or the like, the superconducting interconnect substrate 260 in accordance with the structure of example device 400. It is to be further understood that the example device 400 includes a portion of the superconducting interconnect substrate 260 and is not limited to only the connections and structures shown therein. The die 310 includes an example first die-side interconnect structure 410 and a second die-side interconnect structure 412.

The first die-side interconnect structure 410 includes at least one superconducting element integrated into the wafer die of the qubit die 310. The first die-side interconnect structure 410 can be a doped, deposited, plated, or like portion on or in the first die 310. The first die-side interconnect structure 410 can include a first die-side electrode pad 430. The first die-side electrode pad 430 can include a metallic layer deposited on the first die-side interconnect structure 410. As one example, the first die-side electrode pad 430 can be or include gold.

The second die-side interconnect structure 412 can correspond in one or more of structure and operation to the first die-side interconnect structure 410. It is to be understood that the die 310 can include an arbitrary number of die-side interconnect structures as required to interconnect the die 310 to the superconducting interconnect substrate 260. The second die-side interconnect structure 412 can include a second die-side electrode pad 432 and a third die-side electrode pad 434. The second die-side electrode pad 432 and the third die-side electrode pad 434 can correspond in one or more of structure and operation to the first die-side electrode pad 430. It is to be understood that the die 310 can include an arbitrary number of die-side electrode pads as required to interconnect the die 310 to the superconducting interconnect substrate 260.

The superconducting interconnect substrate 260 includes a first substrate-side interconnect structure 420, a second substrate-side interconnect structure 422, and a third substrate-side interconnect structure 424.

The first substrate-side interconnect structure 420 includes at least one superconducting element integrated into the wafer die of the superconducting interconnect substrate 260. The first substrate-side interconnect structure 420 can be a doped, deposited, plated, or like portion on or in the superconducting interconnect substrate 260. The first substrate-side interconnect structure 420 can include a first substrate-side electrode pad 440. The first substrate-side electrode pad 440 can correspond in one or more of structure and operation to the first die-side electrode pad 430. The first substrate-side electrode pad 440 can be integrated with the first die-side electrode pad 430 at a first bonding interface 450. The first bonding interface 450 includes a planar surface in which the first die-side electrode pad 430 and the first substrate-side electrode pad 440 are integrally joined together. In some implementations, the first die-side electrode pad 430 and the first substrate-side electrode pad 440 are integrally joined together through a combination of heat and pressure for a predetermined time to result in the intermixing and integration of metallic electrode areas of the first die-side electrode pad 430 and the first substrate-side electrode pad 440 at the bonding surface 450.

The second substrate-side interconnect structure 422 and the third substrate-side interconnect structure 424 can correspond in one or more of structure and operation to the first substrate-side interconnect structure 420. It is to be understood that the superconducting interconnect substrate 260 can include an arbitrary number of substrate-side interconnect structures as required to interconnect the superconducting interconnect substrate 260 to the die 310 or any superconducting device on the superconducting interconnect substrate 260. The second substrate-side interconnect structure 422 can include a second substrate-side electrode pad 442. The third substrate-side interconnect structure 424 can include a third substrate-side electrode pad 444. The second substrate-side electrode pad 442 and the third substrate-side electrode pad 444 can correspond in one or more of structure and operation to the first substrate-side electrode pad 440.

The second bonding interface 452 and the third bonding interface 454 can correspond in one or more of structure and operation to the first bonding interface 450, with respect to their corresponding die-side and substrate-side electrode pads 432, 442, 434 and 444.

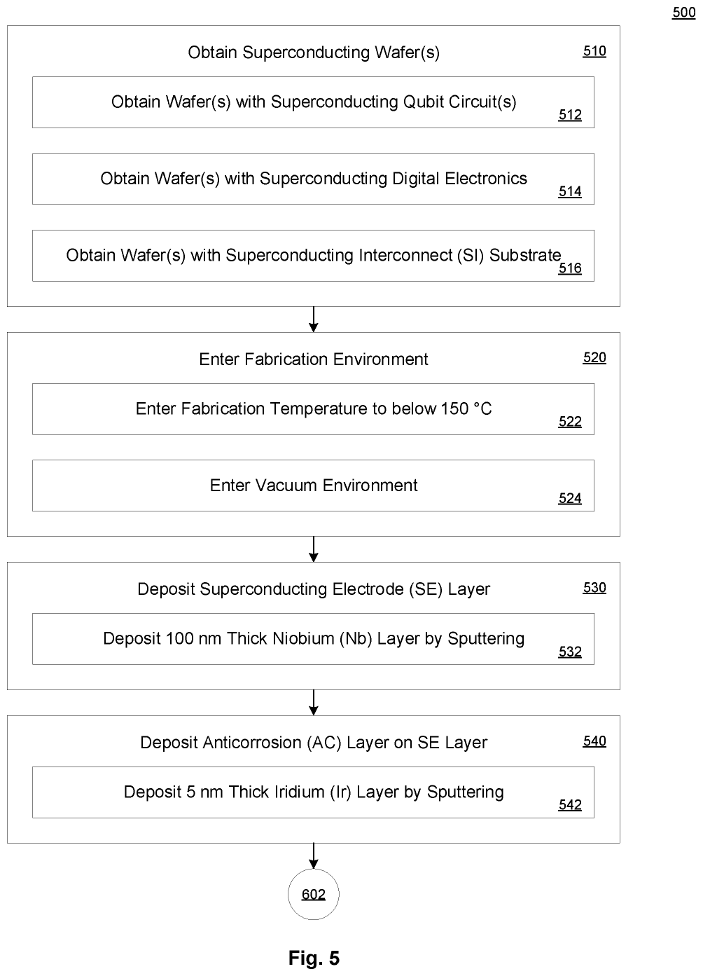

FIG. 5 illustrates an example method of manufacturing a superconducting silicon interconnect substrate with a superconducting quantum processor, in accordance with present implementations. In some implementations, at least one of the example system 100 and the example device 200 performs method 500 according to present implementations. In some implementations, the method 500 begins at step 510.

At step 510, the example system obtains at least one superconducting wafer. In some implementations, step 510 includes at least one of steps 512, 514 and 516. At step 512, the example system obtains at least one wafer having at least one superconducting qubit circuit disposed, fabricated, or the like, therein. At step 514, the example system obtains at least one wafer having at least one superconducting digital electronic device disposed, fabricated, or the like, therein. At step 516, the example system obtains at least one wafer having at least one superconducting interconnect substrate disposed, fabricated, or the like, therein. The method 500 then continues to step 520.

At step 520, the example system enters a fabrication environment. The fabrication environment can be isolated from an ambient environment, external environment, or the like with respect to one or more environmental factors. As one example, environmental factors can include temperature, pressure, atmospheric composition, and the like. In some implementations, step 520 includes at least one of steps 522 and 524. At step 522, the example system enters a fabrication environment with a temperature at or below 150° C. At step 524, the example system enters a vacuum environment at a pressure substantially corresponding to a vacuum pressure. The method 500 then continues to step 530.

At step 530, the example system deposits at least one superconducting electrode layer on at least one surface of the superconducting wafer. The surface of the superconducting wafer can be a planar surface having one or more superconducting devices, processors, interconnect fabrics, and the like, disposed, fabricated, or the like, therein. In some implementations, step 530 includes step 532. At step 532, the example system deposits a 100 nm thick niobium (Nb) layer by sputtering. The method 500 then continues to step NNN.

At step 540, the example system deposits at least one anticorrosion layer on the superconducting electrode layer. In some implementations, step 540 includes step 542. At step 542, the example system deposits a 5 nm thick iridium (Ir) layer by sputtering. The method 500 then continues to step 602.

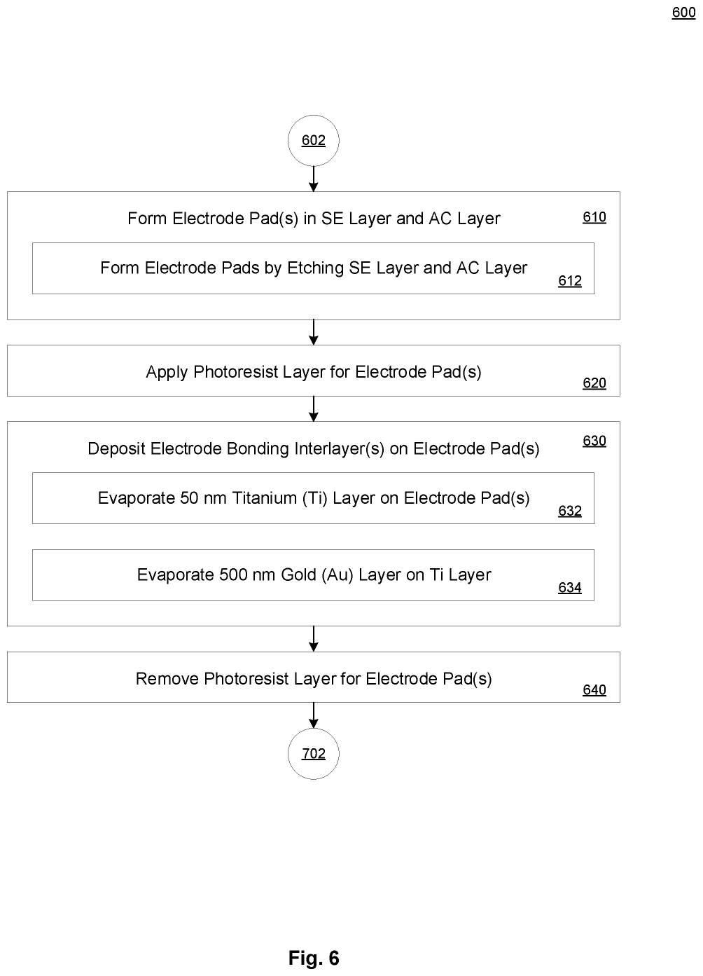

FIG. 6 illustrates an example method of manufacturing a superconducting silicon interconnect substrate with a superconducting quantum processor further to the example method of FIG. 5. In some implementations, at least one of the example system 100 and the example device 200 performs method 600 according to present implementations. In some implementations, the method 600 begins at step 602. The method 600 then continues to step 610.

At step 610, the example system forms at least one electrode pad on at least one of the superconducting electrode layer and the anticorrosion layer. In some implementations, step 610 includes step 612. At step 612, the example system forms electrode pads by etching one or more of the superconducting electrode layer and the anticorrosion layer. The example system can etch through the superconducting electrode layer and the anticorrosion layer to remove material external to complete electrode pads. The method 600 then continues to step 620.

At step 620, the example system applies a photoresist layer for the one or more electrode pads. The example system can apply the photoresist layers to portions of the superconducting wafer not associated with electrode pad positions. As one example, the photoresist layer can be a mask layer leaving exposed one or more portions of the superconducting wafer The method 600 then continues to step 630.

At step 630, the example system deposits one or more electrode bonding interlayers on the electrode pads. In some implementations, step 630 includes at least one of steps 632 and 634. At step 632, the example system evaporates a 50 nm titanium layer Ti on the electrode pads. The Ti layer can advantageously assist in bonding of the Au electrode pads during a flip-chip process. At step 634, the example system evaporates a 500 nm gold (Au) layer on the titanium layer. A 500 nm Au layer can advantageously provide sufficient bonding depth and structure to absorb heat and pressure uniformly during flip-chip bonding. The method 600 then continues to step 640.

At step 640, the example system removes the photoresist layer for the electrode pads. It is to be understood that application of the photoresist is advantageous for at least the deposition of the titanium and gold layers on the electrode pads. The method 600 then continues to step 702.

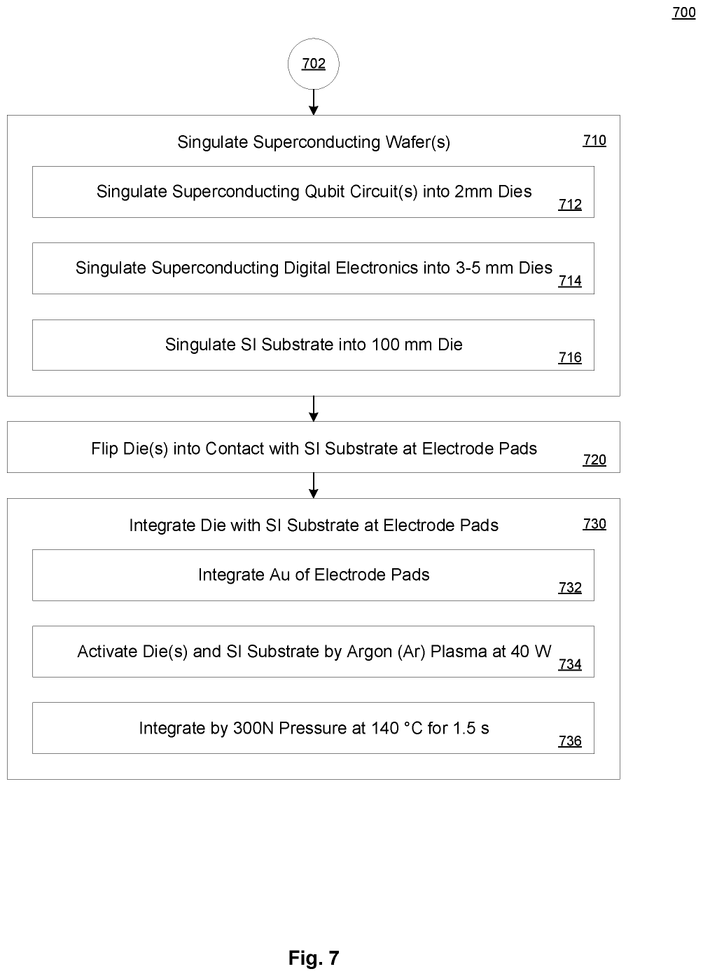

FIG. 7 illustrates an example method of manufacturing a superconducting silicon interconnect substrate with a superconducting quantum processor further to the example method of FIG. 6. In some implementations, at least one of the example system 100 and the example device 200 performs method 700 according to present implementations. In some implementations, the method 700 begins at step 702. The method 700 then continues to step 710.

At step 710, the example system singulates at least one superconducting wafer. The example system can singulate the superconducting wafer by cutting, dicing, and the like. In some implementations, step 710 includes at least one of steps 712, 714 and 716. At step 712, the example system singulates a superconducting qubit circuit into one or more 2 mm dies. As one example, the example system can singulate the superconducting wafer into one or more superconducting qubit circuits from a portion of a superconducting wafer associated with a die size of 2 mm by 2 mm square. At step 714, the example system singulates a superconducting digital electronic device into one or more dies between 3 mm and 5 mm. As one example, the example system can singulate the superconducting wafer into one or more superconducting digital electronic devices from a portion of a superconducting wafer associated with a die size of 3 mm by 3 mm square, 4 mm by 4 mm square, or 5 mm by 5 mm square. At step 736, the example system singulates a superconducting interconnect substrate into one or more 100 mm dies. As one example, the example system can singulate the superconducting wafer into one or more interconnect substrate from a portion of a superconducting wafer associated with any die size. The method 700 then continues to step 720.

At step 720, the example system flips one or more dies into contact with the superconducting interconnect substrate at one or more electrode pads. The example system can flip one or more of a superconducting qubit circuit and a superconducting digital electronic device into contact with the superconducting interconnect substrate. The flip can be achieved by a flip-chip process in which electrode pads of a superconducting qubit circuit or a superconducting digital electronic device are aligned and placed in contact with one another. The method 700 then continues to step 730.

At step 730, the example system integrates at least one die with the superconducting interconnect substrate. In some implementations, step 730 includes at least one of steps 732, 734 and 736. At step 732, the example system integrates the die with the superconducting interconnect substrate by integrating corresponding gold layers thereof in contact with each other at a bonding surface of the gold layers. At step 734, the example system activates the die and the superconducting interconnect substrate in contact with each other by an argon (Ar) plasma at 40 W. The Ar plasma treatment can advantageously sputter off surface impurities to achieve better Au—Au bond between electrode pads during the flip-chip bonding. As one example, the Ar plasma treatment can be substantially 3 min. At step 736, the example system integrates the die with the superconducting interconnect substrate by concurrently applying one or more of pressure, temperature and time. As one example, applied pressure can be up to 300 N applied to one or more of the die and the superconducting interconnect substrate in a direction perpendicular to the plane of the bonding surface of the gold layers. As another example, applied temperature can be 140 C or a temperature at or below 150 C. As another example, time of application of one or more of the applied pressure and the applied temperature can be substantially 1.5 s. Application of pressure at 300 N and temperature of 140 C for 1.5 s advantageously results in a shear force threshold of 150 N, below which the die and the superconducting can withstand separation. In some implementations, the method 700 ends at step 730.

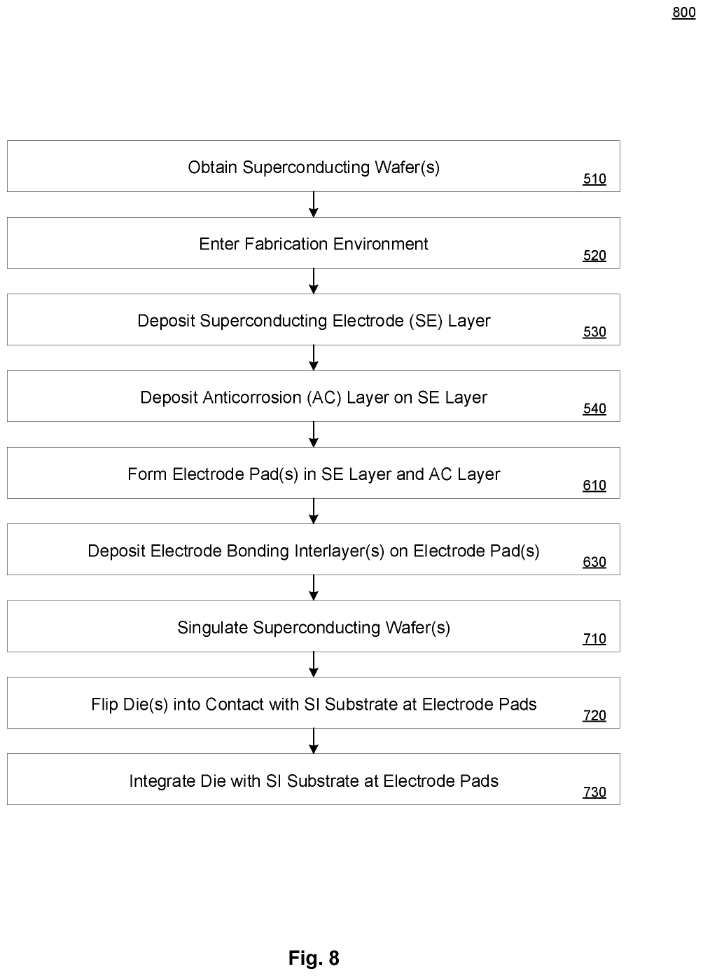

FIG. 8 illustrates a further example method of manufacturing a superconducting silicon interconnect substrate with a superconducting quantum processor, in accordance with present implementations. In some implementations, at least one of the example system 100 and the example device 200 performs method 800 according to present implementations. In some implementations, the method 800 begins at step 510. It is to be understood that steps 510, 520, 530, 540, 610, 630, 710, 720 and 730 of method 800 can correspond at least partially to corresponding steps 510, 520, 530, 540, 610, 630, 710, 720 and 730 of respective methods 500, 600 and 700.

At step 510, the example system obtains at least one superconducting wafer. The method 800 then continues to step 520. At step 520, the example system enters a fabrication environment. The method 800 then continues to step 530. At step 530, the example system deposits at least one superconducting electrode layer on at least one surface of the superconducting wafer. The method 800 then continues to step 540. At step 540, the example system deposits at least one anticorrosion layer on the superconducting electrode layer. The method 800 then continues to step 610. At step 610, the example system forms at least one electrode pad on at least one of the superconducting electrode layer and the anticorrosion layer. The method 800 then continues to step 630. At step 630, the example system deposits one or more electrode bonding interlayers on the electrode pads. The method 800 then continues to step 710. At step 710, the example system singulates at least one superconducting wafer. The method 800 then continues to step 720. At step 720, the example system flips one or more dies into contact with the superconducting interconnect substrate at one or more electrode pads. The method 800 then continues to step 730. At step 730, the example system integrates at least one die with the superconducting interconnect substrate. In some implementations, the method 800 ends at step 730.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

The foregoing description of illustrative implementations has been presented for purposes of illustration and of description. It is not intended to be exhaustive or limiting with respect to the precise form disclosed, and modifications and variations are possible in light of the above teachings or may be acquired from practice of the disclosed implementations. It is intended that the scope of the invention be defined by the claims appended hereto and their equivalents.

1. A quantum computing device comprising:
a quantum processor operable at a cryogenic temperature;
a superconducting input controller operable at the cryogenic temperature and operatively coupled to the quantum processor by a first digital input channel; and
a superconducting output controller operable at the cryogenic temperature and operatively coupled to the quantum processor by a second digital input channel.

2. The quantum computing device of claim 2, wherein the first digital input channel and the second digital input channel each respectively comprise a single flux quantum digital channel.

3. The quantum computing device of claim 1, further comprising:
a superconducting interconnect substrate operable at the cryogenic temperature, including an interconnect electrode pad disposed thereon, and operatively coupled at the interconnect electrode pad to a corresponding interconnect electrode pad of the quantum processor.

4. The quantum computing device of claim 3, wherein the first interconnect electrode pad is integrated with the interconnect electrode pad.

5. The quantum computing device of claim 3, wherein the first interconnect electrode pad is integrated with the interconnect electrode pad at a bonding interface therebetween.

6. (canceled)

7. The quantum computing device of claim 1, wherein the superconducting input controller comprises a microwave input processor operable to receive one or more analog microwave signals.

8. The quantum computing device of claim 1, wherein the superconducting input controller comprises a microwave input processor operable to generate one or more single flux quantum digital signals.

9. The quantum computing device of claim 1, wherein the superconducting output controller comprises a Josephson photomultiplier operable to receive one or more single flux quantum digital signals.

10. The quantum computing device of claim 1, wherein the superconducting output controller comprises a Josephson photomultiplier operable to generate one or more corresponding binary signals.

11. A quantum processor device, comprising:
a superconducting interconnect substrate operable at a cryogenic temperature; and
a plurality of qubit dies operable at the cryogenic temperature and operatively coupled to the superconducting interconnect substrate.

12. The quantum processor device of claim 11, wherein the plurality of qubit dies is integrated with the superconducting interconnect substrate at a bonding interface between a corresponding qubit die electrode pad and a corresponding interconnect substrate electrode pad.

13. The quantum processor device of claim 12, wherein the bonding interface can withstand a shear force of up to 150 N.

14. The quantum processor device of claim 12, wherein each of the plurality of qubit dies respectively includes the corresponding qubit die electrode pad.

15. The quantum processor device of claim 12, wherein the superconducting interconnect substrate includes a corresponding interconnect substrate electrode pad.

16. A method of manufacturing a quantum computing device, the method comprising:
depositing a superconducting electrode layer on at least a portion of a superconducting wafer;
forming a plurality of electrode pads on the superconducting electrode layer;
depositing an electrode bonding interlayer on the electrode pads;
singulating the superconducting wafer into a first superconducting die including a first electrode pad among the plurality and a second superconducting die including a second electrode pad among the plurality; and
integrating the first superconducting die with the second superconducting die at a bonding interface between the first electrode pad and the second electrode pad.

17. The method of claim 16, further comprising:
depositing an anticorrosion layer on the superconducting electrode layer,
wherein the forming the plurality of electrode pads further comprises forming the plurality of electrode pads on the superconducting electrode layer and the anticorrosion layer.

18. (canceled)

19. The method of claim 16, wherein the integrating the first superconducting die with the second superconducting die further comprises:
applying pressure of up to 300N at up to 140° C. to the first superconducting die and the second superconducting die, and in a direction substantially orthogonal to a planar surface corresponding to the bonding interface.

20-21. (canceled)

22. The method of claim 16, further comprising:
contacting the first electrode pad to the second electrode pad by flipping the first superconducting die or the second superconducting die.

23. The method of claim 16, wherein the superconducting electrode layer comprises niobium, the anticorrosion layer comprises iridium, and the electrode bonding interlayer comprises one or more of titanium and gold.

24-26. (canceled)

27. The method of claim 16, further comprising:
depositing the superconducting electrode layer by sputtering;
depositing the anticorrosion layer by sputtering; and
depositing the electrode bonding interlayer by evaporation.

28-29. (canceled)
